(19) United States
(12) Patent Application Publication
(10) Pub. No.: US 2012/0198687 A1
(43) Pub. Date: Aug. 9, 2012

(54) INFORMATION HANDLING SYSTEM DISPLAY INTEGRATION SYSTEM AND PROCESS

(76) Inventors: David W. Douglas, Austin, TX (US); Liam B. Quinn, Austin, TX (US)

(21) Appl. No.: 13/023,358

(22) Filed: Feb. 8, 2011

(51) Int. Cl. H05K 13/00

(52) U.S. Cl. 29/592.1

(57) ABSTRACT

LCD panel inventory for manufacture of portable information handling systems is managed to support consumer and business information handling systems by adapting LCD panels having a substantially identical construction as the LCD panels are pulled from a common inventory. LCD panels placed in the inventory have a polarizing surface suitable for use with consumer information handling systems and are treated with an anti-glare film when pulled from the inventory for assembly into business information handling systems.

### BACKGROUND OF THE INVENTION

1. Field of the Invention

The present invention relates in general to the field of information handling system manufacture, and more particularly to an information handling system display integration system and process.

2. Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

Portable information handling systems have become widely accepted by business and consumer users as an alternative to desktop information handling systems. In part, portable information handling systems have enjoyed greater acceptance because of the flexibility they provide for use on the move, however, more recently with the greater processing power available from newly developed components, end users have increasingly sought portable information handling systems as a replacement for desktop systems. A portable information handling system typically includes integrated power, such as a battery, and integrated I/O devices, such as a keyboard and display built into the system chassis. Integrated power and I/O devices allow an end user full use of the system free from hard wire connections to peripherals or a fixed power source. Business users take advantage of such flexibility by taking portable information handling systems on business trips to stay in touch through wireless communications, to work while traveling and to provide access to business presentations and forms. Consumer users take advantage of such flexibility by working or reading in hot spots, such as coffee shops, or by watching media entertainment, such as movies.

Although business and consumer portable information handling systems largely overlap in their configurations, one difference that often comes up is the preference of consumer users for a glossy or shiny finish on the integrated display versus the preference of business users for more ergonomic anti-glare finish. Consumers tend to prefer a shiny finish, such as Dell Inc.'s “True Life Polarizer”, because it makes multimedia presentations appear more lifelike. Business users tend to prefer an anti-glare finish as less taxing on vision during lengthy periods of preparing documents. This duopoly compounded by alternate sourcing of a given display panel to maintain continuity of supply means a large and diverse inventory of LCD panels must typically be managed for production of portable information handling systems. Maintaining a large inventory adds to the expense of the manufacture process since the inventory is purchased with capital and stored near production sites. The greater the number of parts that are maintained in inventory, the greater the complexity of having enough parts to meet production needs at each production location. In addition, having a greater number of parts increases the likelihood that some parts will become outdated before they are used, damaged during storage or built into an incorrect system.

### SUMMARY OF THE INVENTION

Therefore a need has arisen for a system and method which reduces the inventory of LCD panels for a given information handling system manufacture process.

In accordance with the present invention, a system and method are provided which substantially reduce the disadvantages and problems associated with previous methods and systems for maintaining LCD panel inventory for the production of portable information handling systems. An inventory of LCD panel supports manufacture of first and second types of information handling systems. LCD panels assembled into the second type of information handling system have a predetermined treatment at the assembly location that is not applied to LCD panels assembled into the first type of information handling systems.

More specifically, LCD panels manufactured at an LCD manufacture location are configured for assembly into a consumer type portable information handling system, such as with a glossy polarized finish. The LCD panels are shipped to a portable information handling system manufacture location and maintained in and LCD panel inventory. LCD panels are pulled from the inventory as needed for manufacture of portable information handling systems. LCD panels used to assemble consumer type portable information handling systems are provided to the manufacture line without alteration to the glossy polarized surface. LCD panels used to assemble business type portable information handling systems are modified with an anti-glare film at a point in the portable information handling system assembly. Thus, an inventory of substantially identical LCD panels support manufacture of both consumer and business type portable information handling systems. After manufacture, the portable information handling systems are shipped from the manufacture location to the end user location.

The present invention provides a number of important technical advantages. One example of an important technical advantage is that the number of different types of LCD panels needed for manufacture of portable information handling systems is reduced by adjusting an existing inventory for multiple uses at the manufacture location. Having fewer types of LCD panels in inventory allows greater flexibility in the manufacture process with fewer numbers of each type of LCD panel. Changes in demand for production of one type of LCD panel are met with related LCD panels by adjusting the number of panels treated with ante-glare film. Better production inventory management reduces manufacture cost and production times to provide high quality products to end users in less time and for less money.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts a block diagram of a portable information handling system;

FIG. 2 depicts a block diagram of a manufacture flow for manufacture of portable information handling systems;

FIG. 3 depicts customization of an LCD panel treated for consumer polarization to adapt to business use with anti-glare treatment; and

FIG. 4 depicts a flow diagram of manufacture of consumer and business portable information handling systems from a common inventory of LCD panels.

### DETAILED DESCRIPTION

Assembly of portable information handling systems for consumer and business use with a common inventory of LCD panels is accomplished by selectively applying a treatment to the LCD panel based on the planned end use of each information handling system. For purposes of this disclosure, an information handling system may include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, or other purposes. For example, an information handling system may be a personal computer, a network storage device, or any other suitable device and may vary in size, shape, performance, functionality, and price. The information handling system may include random access memory (RAM), one or more processing resources such as a central processing unit (CPU) or hardware or software control logic, ROM, and/or other types of nonvolatile memory. Additional components of the information handling system may include one or more disk drives, one or more network ports for communicating with external devices as well as various input and output (I/O) devices, such as a keyboard, a mouse, and a video display. The information handling system may also include one or more buses operable to transmit communications between the various hardware components.

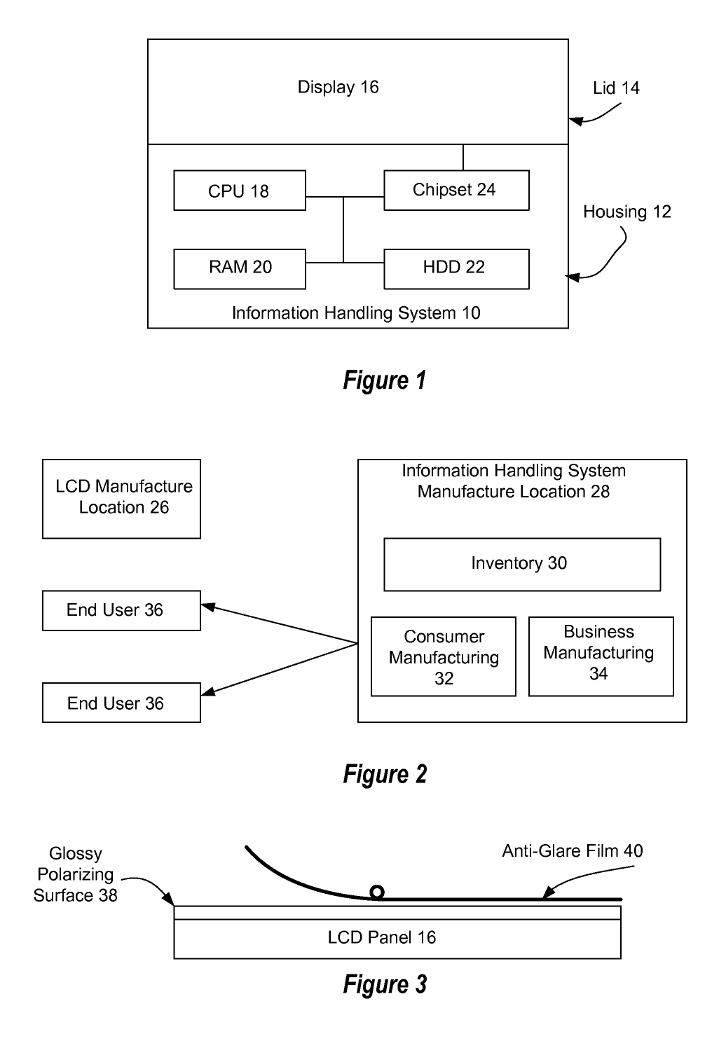

Referring now to FIG. 1, a block diagram depicts a portable information handling system 10. Information handling system 10 is assembled in a housing 12 having a rotationally coupled lid 14 that rotates between open and closed positions to expose and protect a display 16 integrated in lid 14. In alternative embodiments, display 16 may be integrated in information handling system 10 in other forms, such as in a tablet form. Display 16 is, for example, a liquid crystal display (LCD) that presents information has images. Processing components disposed in housing 12 generate information that is presented at display 16. For example, an application running on a CPU 18 with information stored on RAM 20 and hard disk drive 22 generates information that is turned into pixel-based information by a graphics processor in a chipset 24. The pixel-based information is provided to display 16 to generate images for presentation at display 16.

Referring now to FIG. 2, a block diagram depicts a manufacture flow for manufacture of portable information handling systems. LCD panels are manufactured at an LCD manufacture location 26 with a substantially identical construction, meaning that each LCD panel destined for a particular inventory can work with either of two or more types of portable information handling systems. The LCD panels are shipped from location 26 to a portable information handling system manufacture location 28 for assembly into portable information handling systems. An inventory 30 stores LCD panels for use in assembly of two or more types of portable information handling systems. In one embodiment, LCD panels in inventory 30 are configured for use without alteration in a consumer type portable information handling system, such as by having a glossy polarized surface or film. As a consumer manufacture line 32 builds portable information handling systems, it pulls LCD panels from inventory 30 and assembles the LCD panels into portable information handling systems, which are then shipped to end user locations 36. A business manufacture line 34 pulls LCD panels from the same inventory 30 for assembly into business portable information handling systems. The LCD panels pulled from inventory 30 for use in business manufacture line 34 are treated with an anti-glare film that is placed over the glossy polarized surface that is used for consumer portable information handling systems. Portable information handling systems from business manufacture line 34 assembled with LCD panels treated with an anti-glare film placed over the consumer glossy surface are then shipped to business end users 36.

Referring now to FIG. 3, customization is depicted of an LCD panel 16 treated for consumer polarization to adapt to business use with anti-glare treatment. LCD panel 16 is assembled by an LCD manufacturer to have a shiny polarizer surface 38, such as with a polarizing glass or film surface, and then shipped to a portable information handling system manufacture location. Portable information handling systems of a consumer type are built by assembly of LCD panels taken from the inventory in a conventional manner. LCD panels pulled for use in business type portable information handling systems are treated by adding an anti-glare film 40 over the top of polarizing surface 38 during the portable information handling system manufacture process, such as before, during or after assembly of the LCD panel into the portable information handling system. Although FIG. 3 depicts rolling an anti-glare film 38 over polarizing surface 38, in alternative embodiments, alternative ways to cover the shiny polarizing surface with an anti-glare surface may include assembly of an anti-glare cover or spraying an anti-glare film.

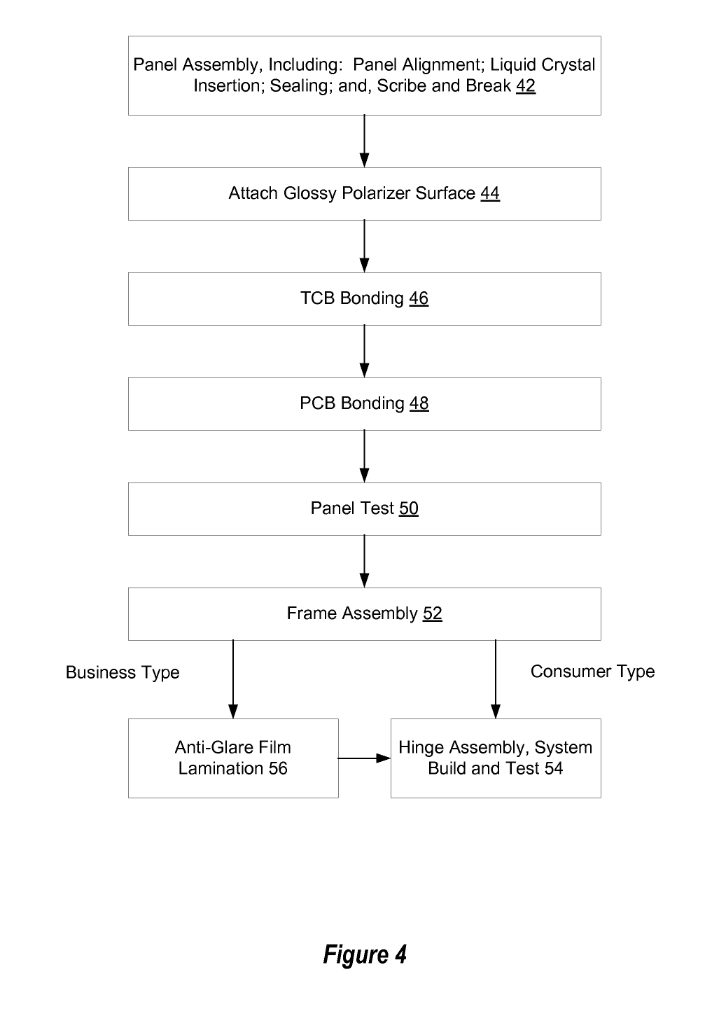

Referring now to FIG. 4, a flow diagram depicts manufacture of consumer and business portable information handling systems from a common inventory of LCD panels. The process begins at step 42 with conventional manufacture steps for manufacture of LCD panels, such as panel alignment, liquid crystal insertion, sealing and scribe and break. At step 44, the LCD panel is treated with a polarizing surface to provide a glossy appearance suitable for consumer information handling systems. At this point in conventional LCD panel manufacture, LCD panels destined for use in business information handling systems are treated with an anti-glare polarizing treatment instead of a glossy treatment. In order to avoid the use of multiple inventories of LCD panels, a common glossy polarizing treatment is used for both business and consumer LCD panels, and an anti-glare treatment is added to business LCD panels when selected for inclusion in business information handling systems. At step 46, TCB bonding is performed and at step 48 PCB bonding is performed. At step 50 panel test is performed and at step 52 panel frame assembly is performed. At this step in manufacture, each LCD panel is prepared for use in a consumer information handling system and the LCD panels are shipped to the information handling system manufacture location for storage in inventory. As consumer information handling systems are built at step 54, LCD panels are pulled from inventory for hinge assembly, system build and system level testing. Manufacture of business portable information handling systems also perform step 54, however, before or during step 54 and anti-glare treatment is provided at step 56 to prepare the LCD panel for use in business systems. The completed portable information handling systems are then ready for shipment to an end user.

Although the present invention has been described in detail, it should be understood that various changes, substitutions and alterations can be made hereto without departing from the spirit and scope of the invention as defined by the appended claims.

What is claimed is:

1. A method for manufacture of portable information handling systems, the method comprising:
assembling plural LCD panels of a first type at a first location;
shipping the LCD panels to a second location;
assembling a first portion of the LCD panels into a first type of portable information handling systems at the second location;
treating a second portion of the LCD panels with a predetermined film at the second location; and
assembling the second portion of LCD panels into a second type of portable information handling systems at the second location.

2. The method of claim 1 wherein the first type of portable information handling systems comprise consumer systems.

3. The method of claim 2 further comprising treating the LCD panels with a polarizing film at the first location.

4. The method of claim 3 wherein treating the second portion further comprises covering the polarizing film with the predetermined film.

5. The method of claim 4 wherein the predetermined film comprises an anti-glare film.

6. The method of claim 5 wherein the second type of information handling systems comprise business systems.

7. The method of claim 1 wherein the predetermined film comprises an anti-glare film.

8. The method of claim 1 wherein the LCD panels comprise touchscreens.

9. The method of claim 1 further comprising shipping the information handling systems to end users.

10. The method of claim 1 further comprising maintaining the LCD panels in a common inventory until selection for each LCD panel for use in the first type or second type of information handling system.

11. A method for manufacture of portable information handling systems, the method comprising:
maintaining an inventory of LCD panels at an information handling system manufacture location, the inventory of LCD panels having substantially identical construction;
pulling a first portion of the LCD panels from the inventory for assembly into a first type of information handling system;
pulling a second portion of LCD panels from the inventory for assembly into a second type of information handling system; and
treating the second portion of LCD panels after the pulling with a predetermined film to adapt the second portion of LCD panels to the second type of information handling system.

12. The method of claim 11 wherein the first type of information handling system comprises a consumer type and the second type of information handling system comprises a business type.

13. The method of claim 12 wherein the predetermined film comprises an anti-glare film.

14. The method of claim 11 wherein the substantially identical construction comprises a polarizing surface.

15. The method of claim 14 wherein treating the second portion further comprises placing the predetermined film over the polarizing surface.

16. The method of claim 15 wherein the predetermined film comprises an anti-glare film.

17. The method of claim 11 wherein treating the second portion comprises applying the predetermined film during assembly of the LCD panel into the information handling system.

18. The method of claim 17 wherein the predetermined film comprises an anti-glare film.

19. The method of claim 11 wherein treating the second portion comprises applying the predetermined film before assembly of the LCD panel into the information handling system.

20. The method of claim 19 wherein the predetermined film comprise an anti-glare film.
